(19) United States
(12) Patent Application Publication
(10) Pub. No.: US 2026/0339871 A1
(43) Pub. Date: Oct. 29, 2026

(54) PROTECTED DIGITAL BUS INTERFACE CIRCUITS WITH AUTOMATIC INTERFACE TYPE SELECTION

(71) Applicant: CIRRUS LOGIC INTERNATIONAL SEMICONDUCTOR LTD., Edinburgh (GB)

(72) Inventors: Bhoodev Kumar, Bee Cave, TX (US); Anindya Bhattacharya, Austin, TX (US); Abhishek Badarinath, Austin, TX (US); Rishi Ahuja, Broomfield, CO (US)

(21) Appl. No.: 19/641,906

(22) Filed: Apr. 8, 2026

Related U.S. Application Data
(60) Provisional application No. 63/795,860, filed on Apr. 28, 2025.

(51) Int. Cl. G06F 13/40; G01R 23/06; H02H 9/04

(52) U.S. Cl. CPC G06F 13/4072; G01R 23/06; H02H 9/046; G06F 2213/0002

(57) ABSTRACT

Interface circuits with protection and automatic interface type selection provide robust connection to interface buses of external devices. The interface circuits include an I/O pad for connection of a clock or data signal to the interface bus, a digital I/O interface coupled to the I/O pad, and an overvoltage protection (OVP) circuit connected to the I/O pad. The OVP circuit includes at least one first clamping circuit and overvoltage detector connected to the I/O pad. The clamping circuit is activated in response to the overvoltage detector detecting an overvoltage condition of a pad voltage at the I/O pad, causing the OVP to clamp the pad voltage. A reconfigurable serial interface supports multiple serial interface types by detecting a frequency of the clock signal configuring the interface according to a frequency range of the detected clock frequency.

### BACKGROUND

### 1. Field of Disclosure

The field of representative embodiments of this disclosure relates to digital interface circuits, and in particular to a protected digital interface with automatic interface type selection.

### 2. Background

Digital bus interfaces provide both inter-circuit and intra-circuit communications. In particular, in inter-circuit communications that allow a system to communicate with an external device, serial bus connections are commonly used, which reduces the number of required interconnects. In automotive subsystems, such as monitoring displays, e.g., fuel gauges, and other gauges for monitoring sensors that may be distributed throughout a vehicle, requirements for handling different serial hardware configurations/protocols is typically needed, as different makes, models, and generations may share either the same monitors/gauges, or the same sensors and configuration should be automatic, rather than requiring configuration at the factory as parts allocations change. Similarly, industrial subsystems may be interchangeable to meet requirements that may vary according to, for example, equipment/models that are used across different production lines. In portable devices, such as tablets, mobile telephones, and smart watches, different configurations and protocols may be needed, and printed circuit board space is typically very limited, therefore, support of multiple interface types may be required.

Such serial bus interfaces typically also require some form of protection against, for example, overvoltage conditions that may occur due to transients induced on wiring. Since the type of interface circuits vary between hardware protocols, e.g., open-collector outputs, push-pull outputs, and current loop outputs, maybe be interfaced to the same input to a system, with the interface type varying across configurations or models of systems, the protection provided for the serial bus interface circuits must provide adequate protection across the different hardware protocols and also not interfere with signaling in any of the possible hardware configurations.

Therefore, it would be advantageous to provide a robust digital bus interface circuit that provides protection of circuits connected to external I/O pads, as well as providing automatic configuration and re-configuration of the digital bus interface from among multiple interface types.

### SUMMARY

The provision of digital bus interfaces including protection of circuits connected to external I/O pads, along with automatic configuration/reconfiguration from among multiple interface types is realized in circuits, integrated circuits and systems including the circuits, along with their methods of operation.

The circuits are interface circuits for connection to an interface bus of an external device. In one aspect, the circuits may include an I/O pad for connection of a clock signal or data signal to the interface bus, a digital I/O interface coupled to the I/O pad, and an overvoltage protection circuit connected to the I/O pad and including at least one first clamping circuit connected to the I/O pad. The overvoltage protection circuit also includes an overvoltage detector coupled to the I/O pad, with the at least one first clamping circuit activated in response to the overvoltage detector detecting an overvoltage condition of a pad voltage at the I/O pad, so that the overvoltage protection circuit clamps the pad voltage at the I/O pad caused by the overvoltage condition.

In another aspect, the interface circuit may be a reconfigurable serial interface circuit that includes an I/O bus for connection to the interface bus that includes a clock signal and a serial interface coupled to the I/O bus. The serial interface may support multiple serial interface types, and may include a frequency detector for detecting a frequency of the clock signal and that, responsive to the frequency detector detecting that the frequency of the clock signal is in a first range, signals the serial interface to configure to communicate with a first one of the multiple serial interface types, and in response to the frequency detector detecting that the frequency of the clock signal is in a second range, signals the serial interface to configure to communicate with a second one of the multiple serial interface types. Detection may be completed within one to two clock cycles.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1A is a simplified schematic diagram illustrating an example connection between an external device 5A with an example integrated circuit 10, in accordance with embodiment of the disclosure.

FIG. 1B is a simplified schematic diagram illustrating an example connection between an external device 5B with example integrated circuit 10, in accordance with embodiment of the disclosure.

FIG. 1C is a simplified schematic diagram illustrating an example connection between an external device 5 with an example integrated circuit 10A, in accordance with another embodiment of the disclosure.

FIG. 2 is a block diagram illustrating example pad circuits 12A, 12B coupled to a device interface circuit 14 that may be used to implement integrated circuit 10 of FIG. 1A and FIG. 1B and integrated circuit 10A of FIG. 1C, in accordance with an embodiment of the disclosure.

FIG. 3 is a simplified schematic diagram illustrating further details of example device interface circuit 14 of FIG. 2, in accordance with an embodiment of the disclosure.

FIG. 4 is a simplified schematic diagram illustrating an example interface detector 20A, that may be used to implement interface detector 20 within interface circuit 14 of FIG. 2, in accordance with an embodiment of the disclosure.

FIG. 5A and FIG. 5B are example timing diagrams 50A and 50B, respectively, illustrating operation of interface detector 20A of FIG. 4, in accordance with an embodiment of the disclosure.

FIG. 6 is a simplified schematic diagram illustrating another example interface detector 20B, that may be used to implement interface detector 20 within interface circuit 14 of FIG. 2, in accordance with another embodiment of the disclosure.

FIG. 7 is a simplified schematic diagram illustrating an example circuit 60, that may be used to implement clamp circuits and pullup circuits within pin circuits 12A, 12B of FIG. 2, in accordance with another embodiment of the disclosure.

FIG. 8A and FIG. 8B are example timing diagrams 70A and 70B, respectively, illustrating operation of example pad circuits 12A, 12B and example interface circuits 14 of FIG. 2 and FIG. 3, in accordance with an embodiment of the disclosure.

### DESCRIPTION OF ILLUSTRATIVE EMBODIMENT

The present disclosure encompasses circuits, integrated circuits implementing the circuits, and their methods of operation. The circuits are interface circuits for connection to an interface bus that connects to other external devices. The circuits include an I/O pad for connection of a clock signal or data signal to the interface bus, a digital I/O interface coupled to the I/O pad, and an overvoltage protection circuit connected to the I/O pad and including at least one first clamping circuit connected to the I/O pad. The overvoltage protection circuit may also include an overvoltage detector coupled to the I/O pad, with the at least one first clamping circuit activated in response to the overvoltage detector detecting an overvoltage condition of a pad voltage at the I/O pad, so that the overvoltage protection circuit clamps the pad voltage at the I/O pad caused by the overvoltage condition. The interface may be a reconfigurable serial interface circuit that includes an I/O bus for connection to the interface bus including a clock signal and a serial interface coupled to the I/O bus and supports multiple serial interface protocols. The serial interface circuit may also include a frequency detector for detecting a frequency of the clock signal and responsive to the frequency detector detecting that the frequency of the clock signal is in a first range, signals the serial interface to configure to communicate with a first one of the multiple serial interface types, and in response to the frequency detector detecting that the frequency of the clock signal is in a second range, signals the serial interface to configure to communicate with a second one of the multiple serial interface types.

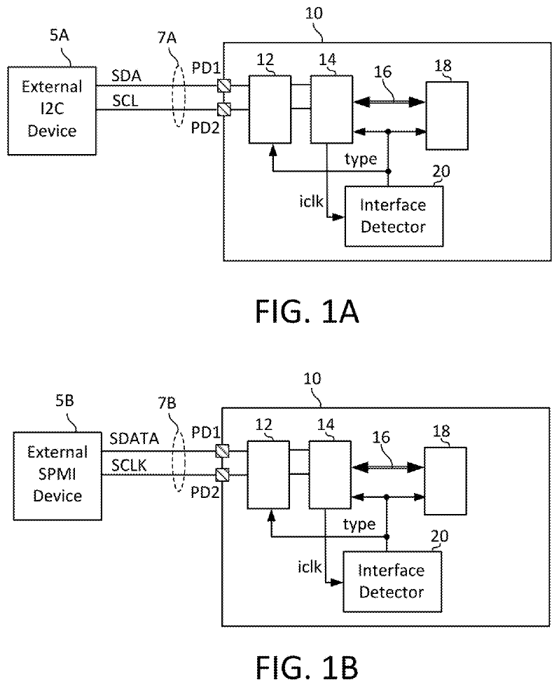

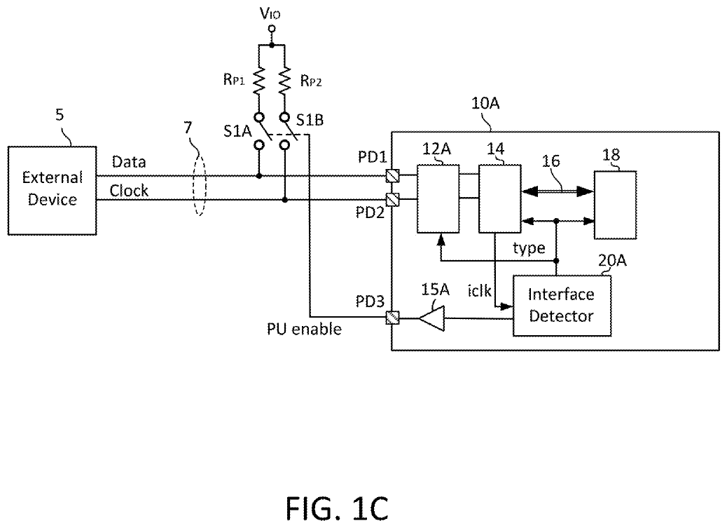

Referring now to FIG. 1A, a simplified schematic diagram illustrating an example connection between an external device 5A with an example integrated circuit 10, is shown in accordance with embodiment of the disclosure. The illustrated example connection is an Inter-Integrated Circuit (I2C) serial bus 7A including a data signal SDA and a clock signal SCL that extend from external device 5A to example integrated circuit 10. Integrated circuit 10 provides pads PD1, PD2 for respective connection of data signal SDA and clock signal SCL. Integrated circuit 10 includes an interface detector 20, a protection/pull-up circuit 12, and a digital interface circuit 14 that provides a data connection to and from other internal device(s) 18 of example integrated circuit 10, such as a microcontroller unit (MCU) or other processing subsystem. Interface detector 20 performs automatic detection of the connected interface type, e.g., I2C in the illustrated example, by evaluating a frequency of the clock signal present on pad PD2, as provided as clock signal iclk from digital interface circuit 14. Interface detector 20 provides a type indication signal type that is used to configure digital interface circuit 14, protection/pull-up circuits 12, and optionally to signal other blocks 18 within integrated circuit 10. The detection of the interface type may be completed within one to two clock cycles, and preferably is performed within one cycle of the clock signal present on pad PD2 before any transactions are initiated on I2C serial bus 7A, so that example integrated circuit 10 is configured to protect and operate an I2C interface over pads PD1, PD2. Since interface types may preferably be used in different frequency ranges, for example, I2C for low frequency communications and SPMI for high-frequency communications, detecting the frequency of the interface clock signal provides a mechanism for determining the interface type of a connected device supplying the clock signal. For example, a device interface may provide for connection of either an I2C interface below 6 MHz, e. g, 1 MHz, or an SPMI interface at a frequency above 6 MHz, e.g., 7 MHz.

Referring now to FIG. 1B, a simplified schematic diagram illustrating an example connection between an external device 5B with example integrated circuit 10, is shown in accordance with embodiment of the disclosure. The illustrated example connection is a System Power Management Interface (SPMI) serial bus 7B, which may be used for any communications purposes, including power management control, and includes a data signal SDATA and a clock signal SCLK that extend from external device 5B to example integrated circuit 10. Pads PD1, PD2 are used for respective connection of data signal SDATA and clock signal SCLK, and integrated circuit 10 operates as described above with reference to FIG. 1A, excepting that type indication signal type will assume a state differing from that in FIG. 1A after interface detector 20 determines that the frequency of clock signal SCLK present on pad PD2 falls within a range corresponding to an SPMI interface, rather than an I2C interface.

Referring now to FIG. 1C, a simplified schematic diagram illustrating an example connection between an external device 5 with an example integrated circuit 10A, is shown in accordance with another embodiment of the disclosure. Example integrated circuit 10A is similar to example integrated circuit 10 described above with reference to FIG. 1A and FIG. 1B, except that rather than providing internal pull-up circuits within protection/pull-up circuit 12, example integrated circuit 10A provides internal protection circuits within a protection circuit 12A and external pull-up resistors R_{P1}, R_{P2} provide pull-up resistance when required by the interface type, and are enabled by switches S1A, S1B, respectively. Switches S1A, S1B are enabled by a control signal PU enable present on a pad PD3 of integrated circuit 10A, which is provided by pad driver 15A that receives an input from interface detector 20A. Example integrated circuit 10A otherwise operates as described above for interface detector 20 of example integrated circuit 10.

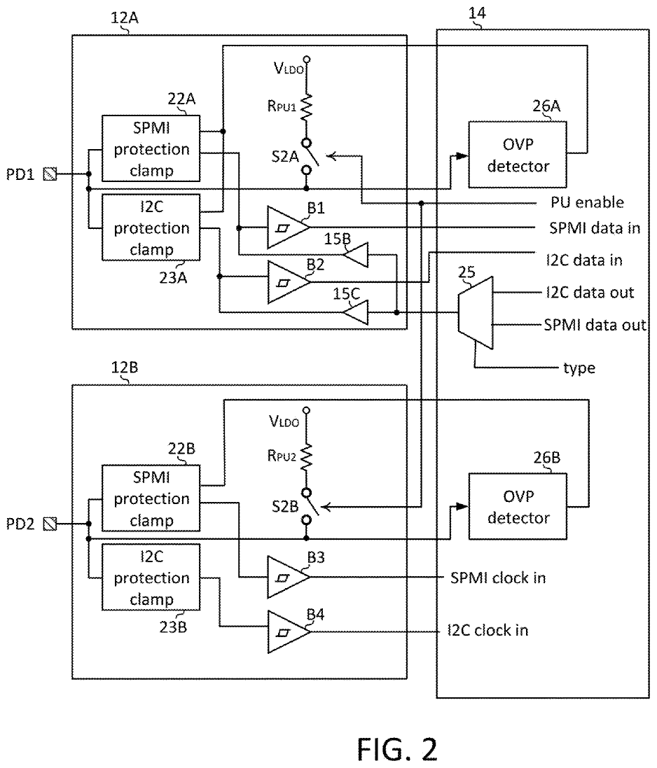

Referring now to FIG. 2, a block diagram illustrating example pad circuits 12A, 12B coupled to a digital interface circuit 14 that may be used to implement integrated circuit 10 of FIG. 1A and FIG. 1B and integrated circuit 10A of FIG. 1C, is shown in accordance with an embodiment of the disclosure. Example pad circuit 12A is an exemplary data pad circuit that includes a pair of pad driver circuits 15B, 15C for providing output data for corresponding interface types, e.g., SPMI and I2C, respectively. Pad driver circuits 15B, 15C, receive a common input from the output of a multiplexer 25, that selects between an I2C data source I2C data out or an SPMI data source SPMI data out, details of which are described in further detail below and which are respectively provided to an SPMI protection clamp circuit 22A and an I2C protection clamp circuit 23A, which may have different designs and structures, depending on protection requirements for the different interfaces. Example pad circuit 12A also includes a pair of receiver circuits B1, B2, which in the illustrated example are Schmitt trigger buffers, that provide output signals SPMI data in and I2C data in for further processing as described in further detail below. Digital interface circuit 14 includes an over-voltage protection (OVP) detector 26A that signals to SPMI protection clamp circuit 22A and I2C protection clamp circuit 23A, that an over-voltage condition exists on pad PD1, so that SPMI protection clamp circuit 22A and I2C protection clamp circuit 23A are enabled to protect circuits in digital interface circuit 14 and other circuits coupled to pad PD1. Example pad circuit 12A also includes a pull-up circuit that includes a pull-up resistor R_{PU1} that may be selectively enabled by a switch S2A to provide pull-up action when the interface type requires, e.g. when the connected interface uses an open-drain output driver type vs. another interface type which might have push-pull drivers, and which also may be enabled to provide part of the over-voltage pad protection mechanism as described in further detail below.

Example pad circuit 12B is an exemplary clock pad circuit that includes a pair of receiver circuits B3, B4, which in the illustrated example are Schmitt trigger buffers, that provide output signals SPMI clock in and I2C clock in for further processing as described in further detail below. Digital interface circuit 14 includes an over-voltage protection (OVP) detector 26B that signals to a SPMI protection clamp circuit 22B and I2C protection clamp circuit 23B, that an over-voltage condition exists on pad PD2, so that SPMI protection clamp circuit 22B and I2C protection clamp circuit 23B are enabled to protect circuits in digital interface circuit 14 and other circuits coupled to pad PD2. Example pad circuit 12B also includes a pull-up circuit that includes a resistor R_{PU2} that may be selectively enabled by a switch S2B to provide pull-up action when the interface type requires.

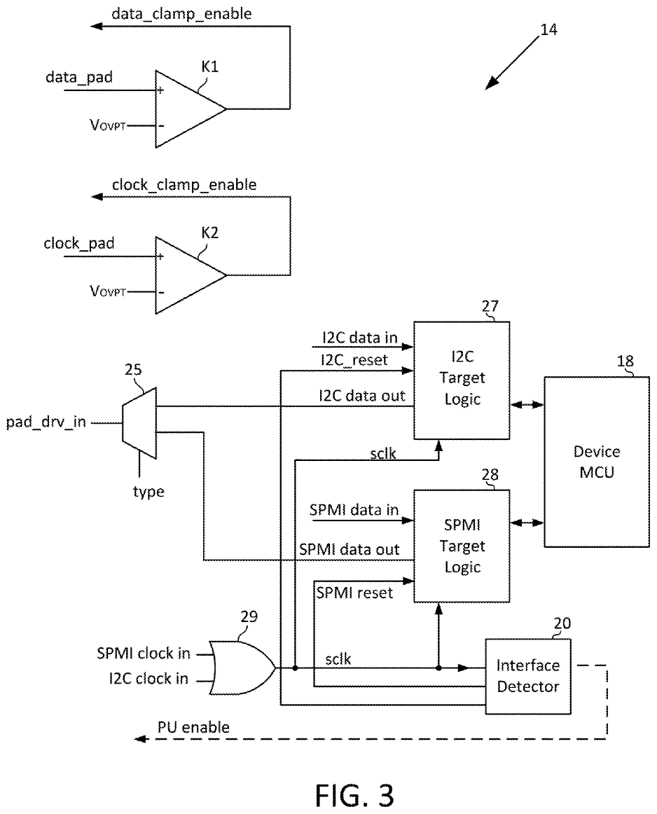

Referring now to FIG. 3, a simplified schematic diagram illustrating further details of example digital interface circuit 14 of FIG. 2, is shown in accordance with an embodiment of the disclosure. As described above, digital interface circuit 14 includes over-voltage protection (OVP) detector 26A, which in the instant example, is implemented by a comparator K1 that compares a signal data_pad from pad PD1 to a threshold voltage V_{OVPT} and generates control signal data_clamp_enable, which is activated when the voltage on pad PD1 exceeds threshold voltage V_{OVP1}, and activates SPMI protection clamp 22A and I2C protection claim 23A of protection circuit 12A of FIG. 2. Similarly, over-voltage protection (OVP) detector 26B of FIG. 2, is implemented in the example by a comparator K2 that compares a signal clock_pad from pad PD2 to threshold voltage V_{OVPT} and generates control signal clock_clamp_enable, which is activated when the voltage on pad PD2 exceeds threshold voltage V_{OVPT}, and activates SPMI protection clamp 22B and I2C protection clamp 23B of protection circuit 12B of FIG. 2.

Example digital interface circuit 14 also includes multiplexer 25, which, as described above, selects between a data output signal I2C data out provided from an I2C target logic block 27 and a data output signal SPMI data out provided from an SPMI target logic block 28. Data input signals I2C data in and SPMI data in are provided to I2C target logic block 27 and SPMI target logic block 28, respectively. I2C target logic block 27 and SPMI target logic block 28 include the digital circuits to transform the input and output signals for their corresponding interface types between the input/output signals provided to, and received by, digital interface circuit 14 to a form required by device MCU 18, which may be parallel or another serial interface, including serial interfaces of data rates that differ from those of the interface (e.g., I2C or SPMI) of an external device connected to pads PD1, PD2. Clock input signals SPMI clock in and I2C clock in are shown combined by a logical-OR gate 29 to generate a single serial clock signal sclk, but may alternatively be routed through selector logic or another circuit that allows for provision of one or more clock signal inputs to interface detector 20, which generates control signals I2C reset and SPMI reset that are provided to I2C target logic 27 and SPMI target logic 28, respectively. Interface detector 20 may, for example, hold both of I2C target logic 27 and SPMI target logic 28 in a reset condition at startup. Drivers of the interface circuits may be held in a high-impedance state during the reset condition. When a clock signal is received on pad PD2, interface detector 20 may determine an interface type of the clock signal by determining that the frequency of clock signal sclk lies within a range of frequencies corresponding to one of the multiple interface types supported by integrated circuit 10, and activating one of I2C target logic 27 and SPMI target logic 28 by de-asserting one of control signals I2C reset or SPMI reset, according to which interface type/hardware protocol is needed to communicate with the external device connected to pads PD1, PD2. Interface detector 20 may also assert control signal PU enable if external pull-ups are present, as in implementations including example integrated circuit 10A as described above, and are needed for the selected interface type. The frequency detection performed by interface detector 20 may control interface selection, output driver configuration, and pull-up activation/de-activation, providing a fully-automatic interface configuration.

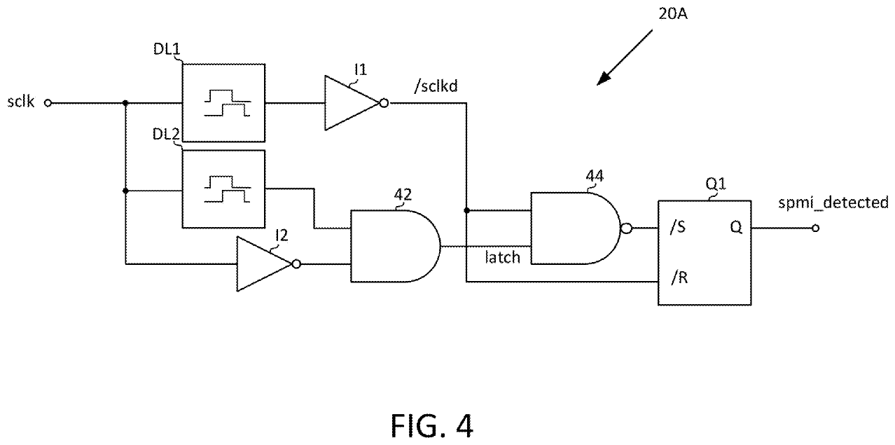

FIG. 4 is a simplified schematic diagram illustrating an example interface detector 20A, that may be used to implement interface detector 20 within interface circuit 14 of FIG. 2, in accordance with an embodiment of the disclosure. Clock signal sclk is provided to a delay line DL1, which delays clock signal sclk, and an inverter I1 inverts the output of delay line DL1 to generate a signal provided to a first input of a logical-NAND gate 44. A second input to logical-NAND gate 44 is provided from a pulse generator formed by a delay line DL2, an inverter I2 and a logical-AND gate 42, the output of which is a de-glitched latching pulse latch occurring at the trailing edge of clock signal sclk, with a duration determined by the delay length of delay line DL2, so that any pulse/glitch shorter than the delay length of delay line DL2 will be suppressed in the output of logical-AND gate 42. Latching pulse latch at the output of logical-AND gate 42 is provided to the second input of logical-NAND gate 44, so that the output of logical-NAND gate 44 remains in a logical-“1” state until latching pulse latch is asserted at the end of the logical-“1” phase of clock signal sclk. Flip-flop Q1 is reset during every logical “0” phase of clock signal sclk, since the inverted reset input of flip-flop Q1 is supplied from the output of inverter I1, and flip-flop Q1 is only set if: at the end of a logical “0” phase of clock signal sclk, the delayed version of clock signal sclk at the output of delay line DL1 is still in a logical-“1” state when the latching pulse at the output of logical-AND gate 42 is asserted. In other words, if latching pulse latch occurs before the delay of delay line DL1 has elapsed, flip-flop Q1 will remain reset. Therefore, for clock frequencies having a period less than the delay period of delay line DL1, the output of flip-flop Q1 will remain reset. By setting the delay period of delay line DL1 to, for example, 167 ns, and the delay of delay line DL2 to, for example 16.7 ns, flip-flop Q1 will remain reset if the frequency of sclk is greater than 6.67 MHz. Conversely, for clock frequencies having a period greater than the delay period of delay line DL1, the output of flip-flop Q1 will remain set, because latching pulse latch occurs after the delay of delay line DL1 has elapsed, and the delayed version of clock signal sclk at the output of delay line DL1 is in a logical-“0” state when the latching pulse at the output of logical-AND gate 42 is asserted. The output of flip-flop Q1 provides an interface type signal spmi_detected, which is asserted of the detected interface type is SPMI, and which is valid after the first half-cycle of clock signal sclk. Thus, example interface detector 20A detects ranges of frequencies that correspond to two distinct interface types, e.g. 0-6 MHz and >6 MHz, which could be extended to support any number of interface types, if the interface types can be categorized by clock frequency ranges.

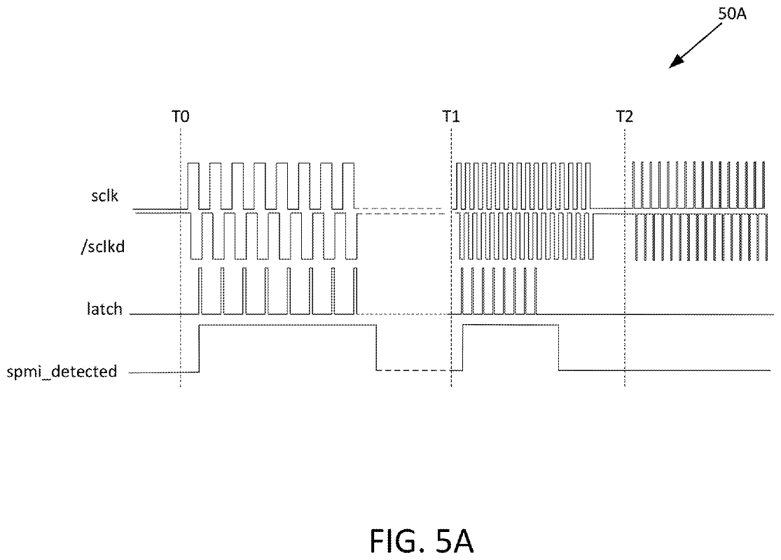

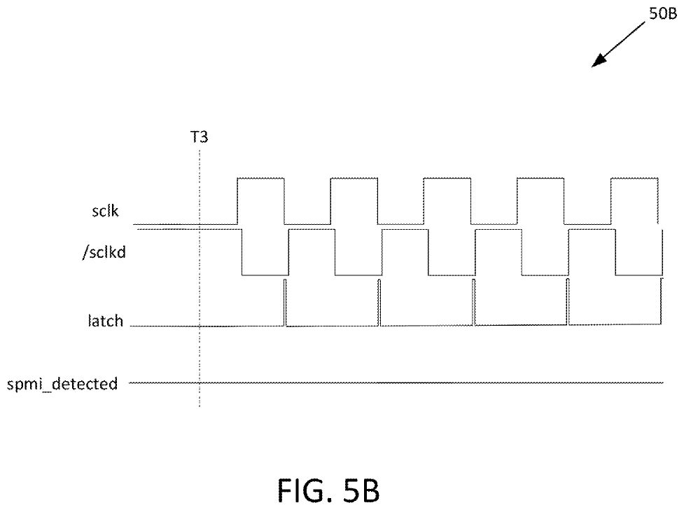

Referring now to FIG. 5A, an example timing diagram 50A depicting the above-described operation of interface detector 20A is shown, in accordance with an embodiment of the disclosure. At a time T0, an SPMI interface circuit is connected with a serial clock sclk frequency of 6 Mhz, causing interface type signal spmi_detected to be asserted at the first falling edge of serial clock sclk, since delayed clock signal/sclkd as qualified by the rising edge control signal latch causes flip-flop Q1 to be set. At a time T1, an SPMI interface circuit is connected with a serial clock sclk frequency of 24 Mhz, again causing interface type signal spmi_detected to be asserted at the first falling edge of serial clock sclk. At a time T2 a narrow serial clock sclk, which may also represent glitches related or unrelated to any connected interface signal does not cause assertion of interface type signal spmi_detected, because assertion of control signal latch is prevented by the de-glitching circuit formed by delay DL2, logical-AND gate 42, and inverter I2.

Referring now to FIG. 5B, another example timing diagram 50B depicting the above-described operation of interface detector 20A is shown, in accordance with an embodiment of the disclosure. At a time T3, an I2C interface circuit is connected with a serial clock sclk frequency of 1 Mhz, causing interface type signal spmi_detected to not be asserted at the first falling edge of serial clock sclk, since the delay of delay DL1 has expired and the state of delayed clock signal /sclkdb is logical-“0” when latching signal latch is asserted.

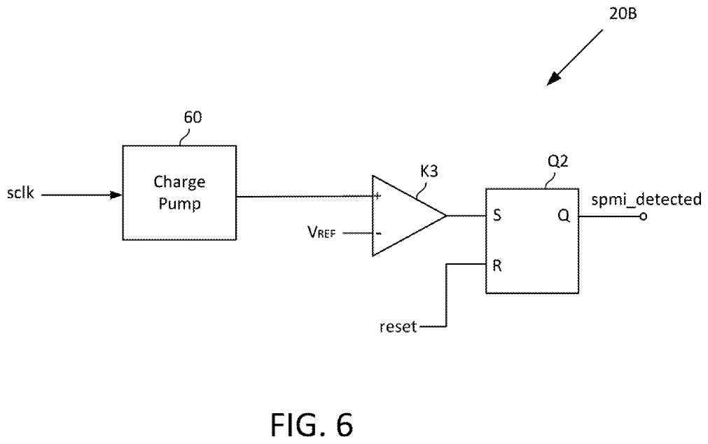

Referring now to FIG. 6, is a simplified schematic diagram illustrating another example interface detector 20B that may be used to implement interface detector 20 within interface circuit 14 of FIG. 2, is shown in accordance with another embodiment of the disclosure. A charge pump circuit 60 receives clock signal sclk as an input, and acts as a frequency-to-voltage converter. Since charge pump circuit 60 integrates the edges of clock signal sclk, the output voltage of charge pump circuit 60 increases as the frequency of clock signal sclk increases. The output of charge pump circuit is compared with a reference voltage V_{REF} using a comparator K3, to determine whether the frequency of clock signal sclk is above or below a threshold frequency corresponding to reference voltage V_{REF}, e.g., to 6 MHz. A flip-flop Q2 latches the output of comparator K3, which is set if the frequency of clock signal sclk is greater than the threshold frequency, and provides the output interface type signal spmi_detected, which is asserted when the detected interface type is SPMI. The edge count-to-voltage characteristic of charge pump 60 may be chosen so that the interface type signal spmi_detected is valid after the first half-cycle of clock signal sclk.

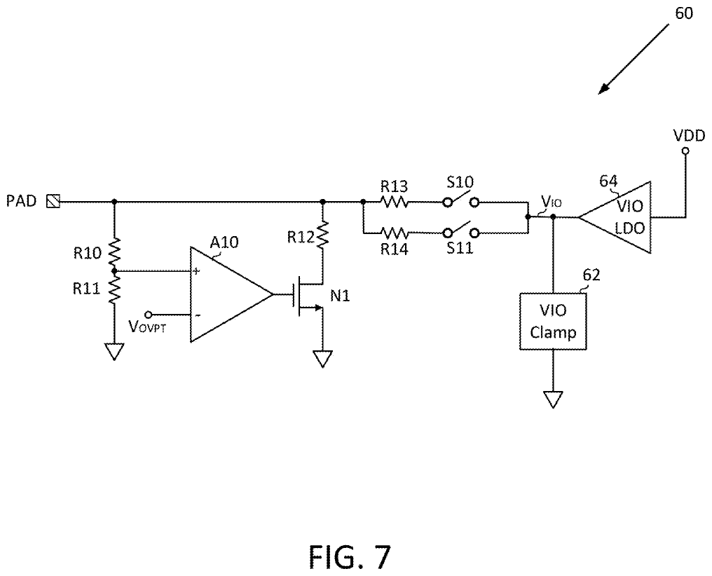

Referring now to FIG. 7, a simplified schematic diagram illustrating an example circuit 60, that may be used to implement clamp circuits and pullup circuits within pin circuits 12A, 12B of FIG. 2, is shown in accordance with another embodiment of the disclosure. Pad PAD, which may be a clock pad or a data signal pad as described above, is connected to a voltage divider formed by resistors R10, R11, and is compared to an overvoltage protection threshold voltage V_{OVPT}, which may differ for the different interface types and as between the clock signal or data signal pads. Amplifier A10, in response to an input voltage that exceeds overvoltage protection threshold voltage V_{OVPT}, drives a clamping transistor N1 which draws current from pad PAD to lower the voltage present at pad PAD. A resistor R12 sets the strength of the pull-down action of a first portion of clamping circuit 60. Another portion of clamping circuit 60, which protects the drive circuits and pull-up circuits connected to clamping circuit 60, as well as other circuits that are connected to a supply voltage V_{IO} provided by a low-dropout regulator (LDO) 64. LDO 64 supplies a pull-up resistor R13 that is selectively coupled to pad PAD by a switch S10, and an additional resistor R14 coupled to pad PAD by a switch S11 that may be activated, by the same OVP control signal that activates the first portion of clamping circuit 60, or by another control signal, to reduce the impedance to supply voltage V_{IO} when a VIO clamp 62 is active, providing further suppression of voltages present on pad PAD that may be greater than supply voltage V_{IO}. Using second clamping circuit also may reduce the required claim size, and reduce the shunt capacitance, presented at pad PAD, thereby improving high-speed signal performance.

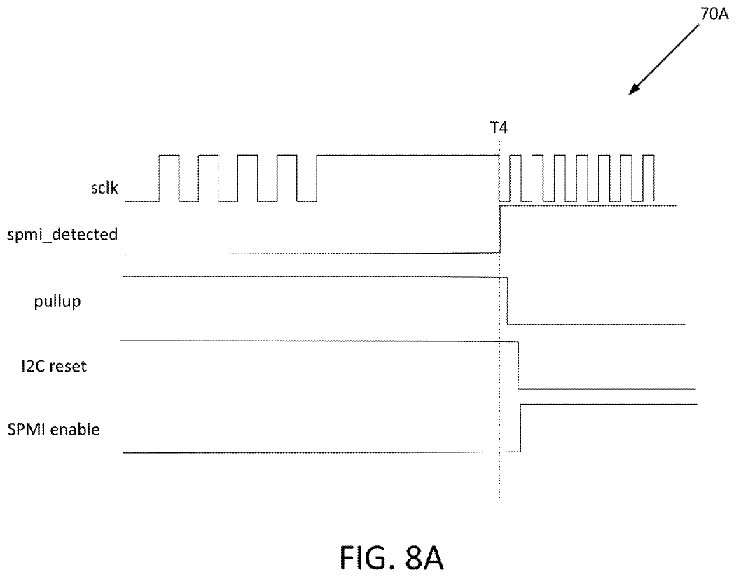

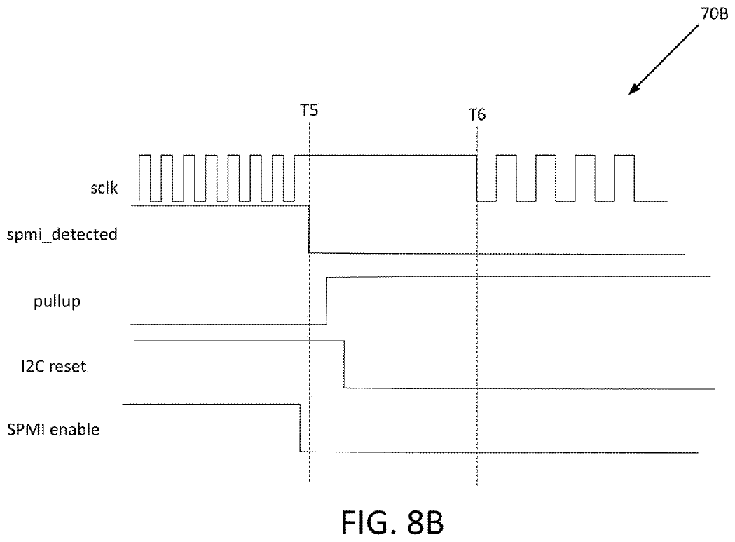

Referring now to FIG. 8A, an example timing diagram 70A depicting operation of example pad circuits 12A, 12B and example interface circuits 14 of FIG. 2 and FIG. 3, is shown in accordance with an embodiment of the disclosure. Timing diagram 70A depicts a transition from an I2C interface operating at 1 MHz to an SPMI interface operating at 6 MHz. At a time T4, an SPMI interface circuit is connected with a serial clock sclk frequency of 6 Mhz, causing interface type signal spmi_detected to be asserted at the first falling edge of serial clock sclk. In response to the assertion of interface type signal spmi_detected, pullups provided for I2C operating mode are disabled by control signal pullup being de-asserted, and the I2C interface circuits are placed in a reset state by assertion of a control signal I2C reset.

Referring now to FIG. 8B, an example timing diagram 70B depicting operation of example pad circuits 12A, 12B and example interface circuits 14 of FIG. 2 and FIG. 3, is shown in accordance with an embodiment of the disclosure. Timing diagram 70B depicts a transition from an SPMI interface operating at 6 MHz to an I2C interface operating at 1 MHz. Prior to time T5, an SPMI interface circuit is connected with a serial clock sclk frequency of 6 MHz, and then at time T5, the bus enters an idle state, causing interface type signal spmi_detected to be de-asserted. In response to the de-assertion of interface type signal spmi_detected, pullups provided for I2C operating mode are enabled by control signal pullup being de-asserted, and the I2C interface circuits are taken out of the reset state by de-assertion of a control signal I2C reset. At time T6, the 1 MHz I2 C clock signal sclk commences and operation in I2C mode commences.

In summary, this disclosure shows and describes interface circuits, and their methods of operation, The interface circuits may be interface circuits for connection to an interface bus of an external device, and may include: an I/O pad for connection of a clock signal or data signal to the interface bus, a digital I/O interface coupled to the I/O pad, and an overvoltage protection circuit connected to the I/O pad. The overvoltage protection circuit may include at least one first clamping circuit connected to the I/O pad and may include an overvoltage detector coupled to the I/O pad. The at least one first clamping circuit may be activated in response to the overvoltage detector detecting an overvoltage condition of a pad voltage at the I/O pad, so that the overvoltage protection circuit clamps the pad voltage at the I/O pad caused by the overvoltage condition.

In some example embodiments, the interface circuits may further include a pull-up circuit with a low-dropout voltage source coupled between the low-dropout voltage source and the I/O pad, and the overvoltage protection circuit may include a second clamping circuit connected to an output of the low-dropout voltage source. In some example embodiments, the pull-up circuit may include a pull-up resistor coupled between the low-dropout voltage source and the I/O pad, so that a capacitive loading of the I/O pad may be reduced by the pull-up resistor coupling the second clamping circuit to the I/O pad. In some example embodiments, the digital I/O interface may be a serial bus interface supporting multiple serial interface types, the I/O pad may be a shared I/O pad used with each of the multiple serial interface types, the digital I/O interface may include separate I/O circuits for each of the multiple serial interface types, and the interface circuit may further include a switching circuit for selectively connecting the pull-up resistor between the low-dropout voltage source and the I/O pad, according to a selected one of the multiple serial interface types. The switching circuit may selectively couple the digital I/O interface and the second clamping circuit to the I/O pad through a protection resistor and disconnect the pull-up resistor in response to detection of the overvoltage condition. In some example embodiments, the pull-up resistor may be an internal pull-up resistor integrated on a die with the interface circuit, and the pull-up resistor may be selectively connected in accordance with the selected one of the multiple interface types. In other some example embodiments, the pull-up resistor may be an external pull-up resistor, and the interface circuit may include a switch control pad for providing a control signal to control an external switch that selectively connects the pull-up resistor to the I/O pad in accordance with the selected one of the multiple interface types.

In some example embodiments, the digital I/O interface may be a serial bus interface supporting multiple serial interface types, and the digital I/O interface may include separate I/O circuits for each of the multiple serial interface types, and the at least one first clamping circuit may include multiple clamping circuits, one for each of the separate I/O circuits. In some example embodiments, the digital I/O interface may include a frequency detector for detecting a frequency of the clock signal and that, in response to the frequency detector detecting that the frequency of the clock signal is in a first range, may signal the digital I/O interface to configure to communicate with a first one of the multiple serial interface types, and that, in response to the frequency detector detecting that the frequency of the clock signal is in a second range, may signal the digital I/O interface to configure to communicate with a second one of the multiple serial interface types. In some example embodiments, the multiple serial interface types may include I2C and SPMI interface types and the threshold frequency may be greater than a maximum I2C clock frequency and less than a minimum SPMI clock frequency.

Additionally, this disclosure also shows and describes interface circuits, and their methods of operation, that are reconfigurable serial interface circuits for connection to an interface bus of an external device, and may include an I/O bus for connection to the interface bus including a clock signal, a serial interface coupled to the I/O bus, and the serial interface may be a serial bus interface supporting multiple serial interface types. The interface circuits may include a frequency detector for detecting a frequency of the clock signal and that may, responsive to the frequency detector detecting that the frequency of the clock signal is in a first range, may signal the serial interface to configure to communicate with a first one of the multiple serial interface types. In response to the frequency detector detecting that the frequency of the clock signal is in a second range, the frequency detector may signal the serial interface to configure to communicate with a second one of the multiple serial interface types. In response to a startup or reset condition, the interface circuit may detect an interface type of a connected external device within one period of the clock signal.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to other types of interface circuits.

What is claimed is:

1. An interface circuit for connection to an interface bus of an external device, the circuit comprising:
an I/O pad for connection of a clock signal or data signal to the interface bus;
a digital I/O interface coupled to the I/O pad;
an overvoltage protection circuit connected to the I/O pad and comprising at least one first clamping circuit connected to the I/O pad and an overvoltage detector coupled to the I/O pad, wherein the at least one first clamping circuit is activated in response to the overvoltage detector detecting an overvoltage condition of a pad voltage at the I/O pad, whereby the overvoltage protection circuit clamps the pad voltage at the I/O pad caused by the overvoltage condition.

2. The interface circuit of claim 1, further comprising a pull-up circuit including a low-dropout voltage source coupled between the low-dropout voltage source and the I/O pad, wherein the overvoltage protection circuit further comprises a second clamping circuit connected to an output of the low-dropout voltage source.

3. The interface circuit of claim 2, wherein the pull-up circuit further comprises a pull-up resistor coupled between the low-dropout voltage source and the I/O pad, whereby a capacitive loading of the I/O pad is reduced by the pull-up resistor coupling the second clamping circuit to the I/O pad.

4. The interface circuit of claim 3, wherein the digital I/O interface is a serial bus interface supporting multiple serial interface types, wherein the digital I/O interface includes separate I/O circuits for each of the multiple serial interface types, and further comprising a switching circuit for selectively connecting the pull-up resistor between the low-dropout voltage source and the I/O pad, according to a selected one of the multiple serial interface types, and wherein the switching circuit further selectively couples the digital I/O interface and the second clamping circuit to the I/O pad through a protection resistor and disconnects the pull-up resistor in response to detection of the overvoltage condition.

5. The interface circuit of claim 4, wherein the pull-up resistor is an internal pull-up resistor integrated on a die with the interface circuit, and wherein the pull-up resistor is selectively connected in accordance with the selected one of the multiple interface types.

6. The interface circuit of claim 4, wherein the pull-up resistor is an external pull-up resistor, and wherein the interface circuit further comprises a switch control pad for providing a control signal to control an external switch that selectively connects the pull-up resistor to the I/O pad in accordance with the selected one of the multiple interface types.

7. The interface circuit of claim 1, wherein the digital I/O interface is a serial bus interface supporting multiple serial interface types, wherein the I/O pad is a shared I/O pad used with each of the multiple serial interface types, wherein the digital I/O interface includes separate I/O circuits for each of the multiple serial interface types, and wherein the at least one first clamping circuit comprises multiple clamping circuits, one for each of the separate I/O circuits.

8. The interface circuit of claim 7, wherein the digital I/O interface includes a frequency detector for detecting a frequency of the clock signal and responsive to the frequency detector detecting that the frequency of the clock signal is in a first range, signals the digital I/O interface to configure to communicate with a first one of the multiple serial interface types, and in response to the frequency detector detecting that the frequency of the clock signal is in a second range, signals the digital I/O interface to configure to communicate with a second one of the multiple serial interface types.

9. The interface circuit of claim 7, wherein the multiple serial interface types include I2C and SPMI interface types.

10. A reconfigurable serial interface circuit for connection to an interface bus of an external device, the circuit comprising:
an I/O bus for connection to the interface bus including a clock signal;
a serial interface coupled to the I/O bus, wherein the serial interface is a serial bus interface supporting multiple serial interface types; and
a frequency detector for detecting a frequency of the clock signal and responsive to the frequency detector detecting that the frequency of the clock signal is in a first range, signals the serial interface to configure to communicate with a first one of the multiple serial interface types, and in response to the frequency detector detecting that the frequency of the clock signal is in a second range, signals the serial interface to configure to communicate with a second one of the multiple serial interface types.

11. The interface circuit of claim 10, wherein the multiple serial interface types include I2C and SPMI interface types.

12. The interface circuit of claim 10, wherein the frequency detector compares the clock signal to a delayed version of the clock signal to determine whether or not the frequency of the clock is above or below a threshold frequency corresponding to a boundary between the first range and the second range.

13. The interface circuit of claim 12, wherein the multiple serial interface types consist of I2C and SPMI interface types, wherein the first serial interface type is I2C, wherein the second serial interface type is SPMI and wherein the threshold frequency is greater than a maximum I2C clock frequency and less than a minimum SPMI clock frequency.

14. The interface circuit of claim 13, wherein, in response to a startup or reset condition, the interface circuit detects an interface type of a connected external device within one period of the clock signal.

15. The interface circuit of claim 10, wherein the frequency detector includes a charge pump that generates a detection voltage in conformity with the frequency of the clock, and wherein the frequency detector compares the detection voltage to a threshold voltage to determine whether or not the frequency of the clock is above or below a threshold frequency corresponding to a boundary between the first range and the second range.

16. A method of connecting to an interface bus of an external device, the method comprising:
connecting a clock signal or data signal of the interface bus to an I/O pad of an integrated circuit, wherein the integrated circuit has a digital I/O interface coupled to the I/O pad;
providing an overvoltage protection circuit of the integrated circuit that is connected to the I/O pad and includes at least one first clamping circuit connected to the I/O pad;
detecting an overvoltage condition of a pad voltage at the I/O pad; and
activating the at least one first clamping circuit in response to detecting the overvoltage condition, whereby the overvoltage protection circuit clamps the pad voltage at the I/O pad caused by the overvoltage condition.

17. The method of claim 16, further comprising coupling a pull-up circuit including a low-dropout voltage source between the low-dropout voltage source and the I/O pad, wherein the overvoltage protection circuit further comprises a second clamping circuit connected to an output of the low-dropout voltage source.

18. The method of claim 17, further comprising providing a pull-up resistor coupled between the low-dropout voltage source and the I/O pad, whereby a capacitive loading of the I/O pad is reduced by the pull-up resistor coupling the second clamping circuit to the I/O pad.

19. The method of claim 18, wherein the digital I/O interface is a serial bus interface supporting multiple serial interface types, wherein the I/O pad is a shared I/O pad used with each of the multiple serial interface types, wherein the digital I/O interface includes separate I/O circuits for each of the multiple serial interface types, and wherein the method comprises:
selectively connecting the pull-up resistor between the low-dropout voltage source and the I/O pad according to a selected one of the multiple serial interface types; and
responsive to detection of the overvoltage condition, selectively coupling the digital I/O interface and the second clamping circuit to the I/O pad through a protection resistor and disconnecting the pull-up resistor.

20. The method of claim 19, wherein the pull-up resistor is an internal pull-up resistor integrated on a die with the interface circuit, and wherein the pull-up resistor is selectively connected in accordance with the selected one of the multiple interface types.

21. The method of claim 19, wherein the pull-up resistor is an external pull-up resistor, and wherein the method further comprises providing a control signal to a switch control pad to control an external switch that selectively connects the pull-up resistor to the I/O pad in accordance with the selected one of the multiple interface types.

22. The method of claim 16, wherein the digital I/O interface is a serial bus interface supporting multiple serial interface types, wherein the digital I/O interface includes separate I/O circuits for each of the multiple serial interface types, and wherein the at least one first clamping circuit comprises multiple clamping circuits, one for each of the separate I/O circuits.

23. The method of claim 22, further comprising:
detecting a frequency of the clock signal; and
responsive to detecting that the frequency of the clock signal is in a first range, signaling the digital I/O interface to configure to communicate with a first one of the multiple serial interface types;
responsive to detecting that the frequency of the clock signal is in a second range, signaling the digital I/O interface to configure to communicate with a second one of the multiple serial interface types.

24. The method of claim 22, wherein the multiple serial interface types include I2C and SPMI interface types.

25. A method of connecting to an interface bus of an external device, the method comprising:
providing an I/O bus for connection to the interface bus including a clock signal;
providing serial interface coupled to the I/O bus, wherein the serial interface is a serial bus interface supporting multiple serial interface types;
detecting a frequency of the clock signal;
responsive to detecting that the frequency of the clock signal is in a first range, signaling the serial interface to configure to communicate with a first one of the multiple serial interface types; and
responsive to detecting that the frequency of the clock signal is in a second range, signaling the serial interface to configure to communicate with a second one of the multiple serial interface types.

26. The method of claim 25, wherein the multiple serial interface types include I2C and SPMI interface types.

27. The method of claim 25, wherein the detecting the frequency of the clock signal compares the clock signal to a delayed version of the clock signal to determine whether or not the frequency of the clock is above or below a threshold frequency corresponding to a boundary between the first range and the second range.

28. The method of claim 27, wherein the multiple serial interface types consist of I2C and SPMI interface types, wherein the first serial interface type is I2C, wherein the second serial interface type is SPMI and wherein the threshold frequency is greater than a maximum I2C clock frequency and less than a minimum SPMI clock frequency.

29. The method of claim 28, wherein, in response to a startup or reset condition, the interface circuit detects an interface type of a connected external device within one period of the clock signal.

30. The method of claim 25, wherein the detecting the frequency of the clock signal comprises:
generating a detection voltage in conformity with the frequency of the clock with a charge pump; and
comparing the detection voltage to a threshold voltage to determine whether or not the frequency of the clock is above or below a threshold frequency corresponding to a boundary between the first range and the second range.
